(19) United States
(12) Patent Application Publication
(10) Pub. No.: US 2025/0387869 A1
(43) Pub. Date: Dec. 25, 2025

(54) CHEMICAL MECHANICAL POLISHING APPARATUS

(71) Applicant: SAMSUNG ELECTRONICS CO., LTD., Suwon-si (KR)

(72) Inventors: Jaehyeon LIM, Suwon-si (KR); Hoyoung KIM, Suwon-si (KR); Kihyun PARK, Suwon-si (KR); Jongsung PARK, Suwon-si (KR); Junhwan YIM, Suwon-si (KR); Seung Hoon CHOI, Suwon-si (KR); Hyungho CHOI, Suwon-si (KR)

(73) Assignee: SAMSUNG ELECTRONICS CO., LTD., Suwon-si (KR)

(21) Appl. No.: 19/176,465

(22) Filed: Apr. 11, 2025

(30) Foreign Application Priority Data
Jun. 25, 2024 (KR) 10-2024-0083012

(51) Int. Cl. B24B 37/04

(52) U.S. Cl. CPC B24B 37/042

(57) ABSTRACT

A polishing method performed by a polishing apparatus, includes: checking polishing conditions; selecting a first operation mode from among a plurality of operation modes based on polishing conditions; and performing polishing in the selected first operation mode.

### CROSS-REFERENCE TO RELATED APPLICATION(S)

This application is based on and claims priority under 35 U.S.C. § 119 to Korean Patent Application No. 10-2024-0083012, filed on Jun. 25, 2024, in the Korean Intellectual Property Office, the disclosure of which is incorporated by reference herein in its entirety.

### BACKGROUND

The disclosure relates to a chemical mechanical polishing apparatus. Chemical mechanical polishing (CMP) is a process used to polish a substrate, layers on a substrate, or structures on a substrate. Such polishing process may be referred to as a planarization process.

A polishing apparatus is used to perform such a chemical mechanical polishing process. The polishing apparatus may include a polishing pad brought into contact with a surface of a target to be planarized (for example, a substrate). While the substrate and polishing pad are in contact with each other, polishing fluid may be supplied between the substrate and the polishing pad, and the substrate and/or the polishing pad may be rotated or vibrated to polish the surface of the substrate.

However, when a polishing apparatus is used for an extended period, the accumulation of substances in the polishing fluid on the polishing pad may hinder uniform polishing.

### SUMMARY

Provided are a polishing apparatus for preventing uneven accumulation of polishing fluid during a polishing process and a method performed by the polishing apparatus.

According to an aspect of the disclosure, a polishing apparatus comprising: a platen configured to support a polishing pad, the platen being rotatable; a chemical mechanical polishing (CMP) head on the platen, the CMP head being configured to hold a substrate to be processed; a polishing fluid supply device configured to supply a polishing fluid onto the polishing pad, the polishing fluid supply device overlapping the platen in plan view; a conditioner assembly configured to condition the polishing pad; and a controller configured to control the platen, the CMP head, the polishing fluid supply device, and the conditioner assembly, wherein the polishing fluid supply device comprises: a polishing fluid supply nozzle configured to supply the polishing fluid onto the polishing pad; a driver configured to move the polishing fluid supply nozzle; and a connector configured to connect the polishing fluid supply nozzle and the driver, and wherein the controller is configured to set a plurality of operation modes having respectively different moving paths for the polishing fluid supply device and the controller is configured to select one operation mode of the plurality of operation modes, and wherein the polishing fluid supply device is configured to move along a moving path corresponding to the selected operation mode.

According to an aspect of the disclosure, a polishing method performed by a polishing apparatus, includes: checking polishing conditions; selecting a first operation mode from among a plurality of operation modes based on polishing conditions; and performing polishing in the selected first operation mode.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view of a polishing apparatus according to an example embodiment;

FIG. 2 is a schematic cross-sectional view of the polishing apparatus of FIG. 1;

FIGS. 3A to 3E are plan views illustrating movement paths of a polishing fluid supply device depending on various operation modes;

FIG. 4 is a perspective view illustrating a polishing apparatus according to an example embodiment;

FIG. 5 is a schematic cross-sectional view of the polishing apparatus of FIG. 4;

FIG. 6 is a plan view illustrating a path of a polishing fluid supply device in the polishing apparatus of FIG. 4;

FIG. 7 is a plan view illustrating a path of a polishing fluid supply device in the polishing apparatus of FIG. 4;

FIG. 8 illustrates a method of performing a polishing process using a polishing apparatus according to an example embodiment; and

FIG. 9 illustrates a polishing profiles in a radial direction of a polishing pad before and after changing operation mode of a polishing fluid supply device.

### DETAILED DESCRIPTION

Hereinafter, example embodiments will be described with reference to the accompanying drawings.

Example embodiments relate to a polishing apparatus used in a manufacturing process of semiconductor devices. The polishing apparatus is configured to polish a substrate (for example, a semiconductor wafer) used to manufacture semiconductor devices, or at least one layer among various layers on a surface of the substrate. During a polishing process, a substrate to be processed (hereinafter, “target substrate”), such as the substrate or at least one of the various layers on the surface of the substrate, may be placed on a polishing pad, and the target substrate and the polishing pad may be moved relative to each other while supplying polishing fluid SL between the target substrate and the polishing pad to polish the surface of the target substrate. In an example embodiment, the polishing process may be performed based on a state of the target substrate to efficiently polish the target substrate. Hereinafter, the polishing apparatus will be described first, and a method of polishing a target substrate using the polishing apparatus will be described later.

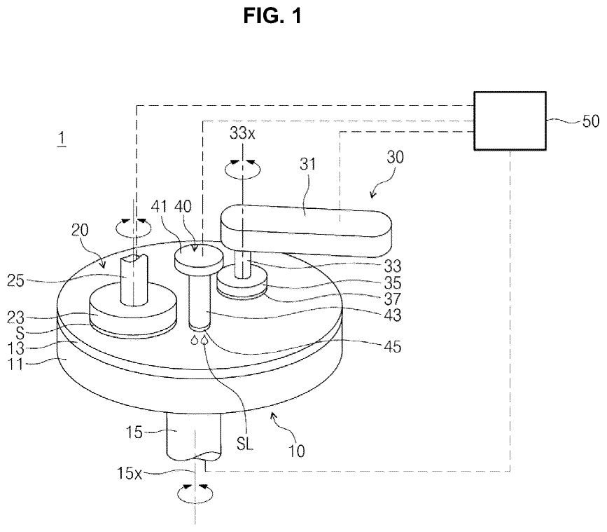

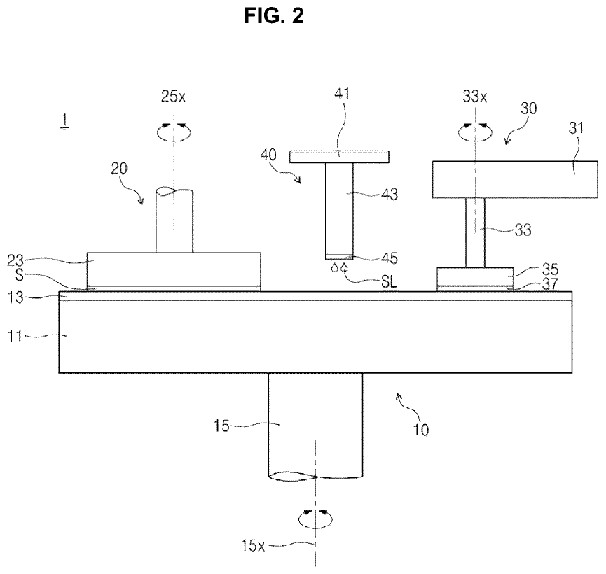

FIG. 1 is a perspective view of a polishing apparatus according to an example embodiment. FIG. 2 is a schematic cross-sectional view of the polishing apparatus of FIG. 1.

Referring to FIGS. 1 and 2, a polishing apparatus 1 according to an example embodiment may include a stage 10 including a polishing pad 13, a CMP assembly 20 placing a target substrate S on the polishing pad 13 to polish the target substrate S, a conditioner assembly 30 conditioning the polishing pad 13, a polishing fluid supply device 40 distributing polishing fluid SL, and a controller 50.

The stage 10 may include a platen 11, the polishing pad 13 on an upper surface of the platen 11, and a drive spindle 15. The platen 11 may have a plate shape with a flat upper surface (for example, a disk shape).

The platen 11 may be connected to the drive spindle 15 and is rotatable around a rotation axis 15x of the drive spindle 15. In an embodiment, a drive motor for driving the platen 11 may be provided at the drive spindle 15 to provide a rotational force to the platen 11 through the drive spindle 15.

In an example embodiment, the platen 11 may perform motions other than rotational movement, such as linear motion. For instance, the platen 11 may perform rotational motion, linear motion, or a combination of those motions. The linear motion may include not only unidirectional motion but also reciprocating motion, and the rotational motion may include spinning motion, turning motion, angular rotational motion, eccentric motion, or combinations of those motions.

The polishing pad 13 may be provided on the platen 11. The polishing pad 13 may be used to contact and polish a surface of the target substrate S.

During a polishing process, the target substrate S may be placed on the polishing pad 13 and may perform rotational and/or linear motion while contacting the polishing pad 13.

Sizes (for example, areas) of the polishing pad 13 and the platen 11 disposed below the polishing pad 13 may be larger than a size (for example, an area) of the target substrate S.

A material of the polishing pad 13 may vary depending on conditions such as a material of a surface to be processed of the target substrate S and polishing particles. For example, the polishing pad 13 may be formed of a polyurethane-based hard pad, a suede-based soft pad, or a sponge. In an embodiment, the polishing pad 13 may be formed of a material having a hardness or rigidity corresponding to a mechanical hardness or rigidity of the surface to be processed. The polishing pad 13 may have a multilayer structure including a plurality of stacked pads. In the polishing pad 13 having a multilayer structure, at least some of the plurality of stacked pads may be different in hardness (or rigidity), and thus the overall hardness or rigidity of the polishing pad 13 may be determined.

In an example embodiment, at least one groove may be disposed on the upper surface of the polishing pad 13 to improve polishing efficiency of the target substrate S. The groove may have at least one of various shapes (for example, concentric, radial, and spiral shapes). The groove may allow the polishing fluid SL to be uniformly supplied between the polishing pad 13 and the target substrate S, or may facilitate the discharge of byproducts formed after the polishing process.

The CMP assembly 20 may hold and support the target substrate S on a lower surface of a CMP head 23 that may be included in the CMP assembly 20. The CMP assembly 20 may move the target substrate S such that the surface to be processed of the target substrate S is provided on the upper surface of the polishing pad 13.

A CMP spindle 25 connected to the CMP head 23 to be rotatable with the CMP head 23. A CMP drive motor for driving the CMP spindle 25 may be connected to the CMP spindle 25.

The target substrate S may include a substrate requiring polishing, or a substrate on which at least one layer and/or structure requiring polishing is formed. The substrate on which at least one layer and/or structure is formed may be used in a manufacturing process of a semiconductor device. For example, the target substrate S may include a semiconductor substrate (formed of a semiconductor material) as well as a metal substrate, a glass substrate, a plastic substrate, or the like. The semiconductor substrate may include a semiconductor element such as silicon (Si) or germanium (Ge), or a compound semiconductor such as silicon carbide (SiC), gallium arsenide (GaAs), indium arsenide (InAs), or indium phosphide (InP), but example embodiments are not limited to those examples. In an embodiment, the target substrate S may include at least one an organic layer, an inorganic layer, an organic-inorganic composite layer, or a metal layer on the substrate.

The CMP head 23 may be configured to be movable in a direction, perpendicular to the surface of the polishing pad 13. The CMP spindle 25 may be connected to the CMP head 23 such that the CMP head 23 may rotate about an axis. A CMP drive motor may provide a rotational force to the CMP spindle 25.

The target substrate S may be held on a lower surface of the CMP head 23 by vacuum suction. In a state in which the CMP head 23 holds and supports the target substrate S, the CMP head 23 may rotate about the rotation axis 25x of the CMP spindle 25 while pressing the target substrate S against the polishing pad 13.

In an example embodiment, the CMP head 23 may perform motions other than rotation. For example, the CMP head 23 may be connected to an arm movable in a radial direction of the platen 11 to move in the radial direction within a plane of the platen 11. The CMP head 23 and the target substrate S (supported by the CMP head 23) may perform linear motion, rotational motion, or a combination of the rotational and linear motions in a lateral (horizontal) direction on the upper surface of the polishing pad 13. In an example embodiment, the CMP head 23 may be swept between an inner side and an outer side of the platen 11 on the upper surface of the polishing pad 13.

In an example embodiment, the platen 11 may perform rotational motion and/or linear motion (for example, simultaneously) with the sweeping of the CMP head 23. In an embodiment, the platen 11 may perform rotational motion and/or linear motion independently of the CMP head 23.

The conditioner assembly 30 may be used to condition (for example, clean and/or regenerate) the polishing pad 13 and may perform a process of polishing the surface of the polishing pad 13. The conditioning process of the polishing pad 13 may be performed between polishing processes of the target substrate S using the CMP assembly 20, or may be performed simultaneously with a polishing process of the target substrate S.

The conditioner assembly 30 may include a conditioner disk 37, a disk head 35 coupled to the conditioner disk 37, and a conditioner spindle part 33 configured to transmit a rotational force to the conditioner disk 37.

The disk head 35 may be coupled to a conditioner disk 37. While the conditioner disk 37 coupled to the disk head 35 is in contact with the polishing pad 13, the conditioner disk 37 may rotate horizontally on the polishing pad 13, allowing the polishing pad 13 to be conditioned.

The conditioner disk 37 may be disposed on a lower surface of the disk head 35. The conditioner disk 37 may include at least one pad among various pads for conditioning the polishing pad 13.

The conditioner disk 37 may include polishing elements, for example, abrasive diamond particles fixed to the conditioner disk 37. The conditioner disk 37 may also include at least one of other abrasive compositions, in addition to or in place of the diamond particles. For example, silicon carbide particles may be used in place of or in addition to the abrasive diamond particles. In an example embodiment, the conditioner disk 37 may include a fixed brush formed of a polymer resin.

The conditioner spindle part 33 may be connected to a conditioner arm 31, and the conditioner arm 31 may be connected to an outer spindle 39. For example, one end of the conditioner arm 31 may be connected to the conditioner spindle part 33.

The conditioner arm 31 may move the disk head 35 and the conditioner disk 37 to an appropriate location on the polishing pad 13.

The conditioner spindle part 35 may be connected to a lower portion of the conditioner arm 31. An upper portion of the conditioner spindle part 35 may be connected to the lower portion of the conditioner arm 31. A lower portion of the conditioner spindle part 35 may be connected to the disk head 35.

In an embodiment, a drive motor is capable of providing a rotational force to the disk head 35 through the conditioner spindle part 33. The drive motor may be connected to the conditioner spindle part 33. The drive motor may rotate the conditioner spindle part 33 and the conditioner disk 37 about a conditioner rotation axis 33x. In an embodiment, the drive motor may be installed within the conditioner arm 31.

A polishing fluid supply device 40 may be provided in the polishing apparatus 1 to supply polishing fluid SL, containing polishing particles for polishing the surface to be processed of the target substrate S, onto the polishing pad 13.

The polishing fluid SL may be provided as a slurry composition including polishing particles and a solvent. The size, type, and/or concentration of the polishing particles used in the polishing process may be selected based on a state of a removing target of the target substrate S (for example, a size of an initial step, a height of a layer, and/or a material of the layer). The polishing particles may include at least one of diamond, silicon carbide (SiC), cubic boron nitride (CBN), silicon dioxide (SiO₂), cerium oxide (CeO₂), or aluminum oxide (Al₂O₃). The polishing fluid SL may further include additives in addition to the polishing particles.

In an example embodiment, the polishing fluid supply device 40 may supply the polishing fluid SL onto the polishing pad 13. In an example embodiment, the polishing apparatus 1 may include a plurality of polishing fluid supply devices 40. When the polishing apparatus 1 includes a plurality of polishing fluid supply devices 40, each of the plurality of polishing fluid supply devices 40 may be independently driven to supply the polishing fluid SL onto the polishing pad 13. The plurality of polishing fluid supply devices 40 may be selected to correspond to different operation modes when operation mode is selected.

In addition, the plurality of polishing fluid supply devices 40 may cooperatively supply the polishing fluid SL onto the polishing pad 13. A portion of the plurality of polishing fluid supply devices 40 may polish fluid supply devices. The polishing fluid supply device of the related art may be used in combination with the polishing fluid supply device 40 corresponding to an example embodiment of the disclosure.

The polishing fluid supply device 40 may include a polishing fluid supply nozzle 45 for supplying the polishing fluid SL onto the polishing pad 13, a driver 41 for changing a location and a movement path of the polishing fluid supply nozzle 45, and a connector 43 connecting the polishing fluid supply nozzle 45 and the driver 41.

The polishing fluid supply nozzle 45 may be a circular plate. The polishing fluid supply nozzle 45 may have a concave portion in a center of the polishing fluid supply nozzle 45. A polishing fluid supply port 451 may be provided in the concave portion. The polishing fluid supply port 451 may be provided in singular or plural.

When the polishing fluid supply ports 451 is provided in plural, the plurality of polishing fluid supply ports 451 may be arranged in a predetermined direction in plan view. However, the arrangement of the polishing fluid supply ports 451 is not limited to the above embodiment. The polishing fluid supply ports 451 may be randomly arranged within the concave portion.

In an example embodiment, the polishing fluid supply ports 451 may include four polishing fluid supply ports, which may be arranged in a 2×2 matrix. However, the shape of the polishing fluid supply nozzle 45 and/or the number and arrangement of the polishing fluid supply ports 451 are illustrated as an example and are not limited to the above example. For example, the polishing fluid supply nozzle 45 may have a rectangular shape, and the polishing fluid supply ports 451 may be arranged in a single row.

The connector 43 may have a columnar shape extending in a vertical direction. A lower end of the connector 43 may be coupled to the polishing fluid supply nozzle 45, and an upper end of the connector 43 may be coupled to the driver 41. In an embodiment, a slurry supply pipe may be connected to the polishing fluid supply nozzle 45, and may be provided in the connector 43. The polishing fluid supply nozzle 45 may discharge the polishing fluid SL, supplied from the slurry supply pipe, onto the polishing pad 13.

The driver 41 may be disposed on the platen 11. The driver 41 may move the connector 43 and the polishing fluid supply nozzle 45 from an upper side of the platen 11 in a direction, parallel to the upper surface of the platen 11. In plan view, the movement path provided by the driver 41 may (for example, completely) overlap the inside of the platen 11. Accordingly, the polishing fluid supply nozzle 45 moves above the platen 11, so that the polishing fluid supply nozzle 45 may provide the polishing fluid SL onto the upper surface of the platen 11.

In an embodiment, the driver 41 may further include a drive motor providing power for moving the polishing fluid supply device 40. In an embodiment, the driver 41 may further include an elevating mechanism moving the connector 43 and the polishing fluid supply nozzle 45 up and down in a vertical direction.

The driver 41 may include a rail serving to move the polishing fluid supply device 40. The rail may extend in a direction, parallel to the upper surface of the platen 11. The driver 41, the connector 43, and the polishing fluid supply nozzle 45 may move along an extension direction of the rail in a direction, parallel to the upper surface of the platen 11.

The polishing fluid supply device 40 may perform rotational motion, linear motion, curvilinear motion, or combinations of those motions in a horizontal direction within a plane formed by the upper surface of the platen 11, in plan view. For example, the polishing fluid supply device 40 may perform motions, such as sweeping, reciprocation, rotation, or zigzagging, on the polishing pad. The polishing fluid supply device 40 may discharge the polishing fluid SL onto the platen 11 while performing the motion.

The controller 50 may be communicatively connected to the platen 11, the CMP assembly 20, the polishing fluid supply device 40, and the conditioner assembly 30, and may transmit command signals to control the platen 11, the CMP assembly 20, the polishing fluid supply device 40, and the conditioner assembly 30. For example, the controller 50 may drive the conditioner assembly 30 by instructing the conditioner assembly 30 on values such as rotational speed and/or rotational torque of a conditioner rotation axis 33x. In an embodiment, the controller 50 may include a central processing unit (CPU) configured to process various types of data and a memory recording various types of data.

In some embodiments, the controller 50 may correspond to or include one or more processors such as the CPU, a graphics processing unit (GPU), an accelerated processing unit (APU), a many integrated core (MIC), a field-programmable gate array (FPGA), a digital signal processor (DSP), a neural processing unit (NPU), or a hardware accelerator.

In an example embodiment, the controller 50 may control whether the polishing fluid supply device 40 has moved and whether the polishing fluid has been supplied. For example, the controller 50 may control values such as the movement path of the polishing fluid supply device 40, the movement direction of the polishing fluid supply device 40, whether the polishing fluid supply nozzle 45 has been opened or closed, slurry supply time, and slurry discharge amount. The polishing fluid supply device 40 may provide the polishing fluid SL onto the polishing pad 13 through the polishing fluid supply nozzle 45 simultaneously with the movement of the polishing fluid supply device 40, or between the movements of the polishing fluid supply device 40, or before or after the movement of the polishing fluid supply device 40. The polishing fluid SL may be continuously or intermittently discharged onto the polishing pad 13 based on settings.

In the embodiment, when controlling the polishing fluid supply device 40, the controller 50 may set the polishing fluid supply device 40 to a plurality of operation modes according to the movement paths. The plurality of operation modes may include corresponding movement paths, respectively. The controller 50 may also select one of the plurality of operation modes. The polishing fluid supply device 40 may move the polishing fluid supply device 40 along a movement path corresponding to the operation mode selected by the controller 50. Each of the operation modes may be set to be different by the controller 50 depending on an object to be polished, the polishing fluid, the polishing process conditions, or the like (hereinafter, “polishing conditions”). The polishing conditions may refer to a pressure applied to a target substrate, rotational speed of a platen, rotational speed of a polishing pad and/or a CMP pad, a flow rate of polishing fluid, a size of each polishing particle, the life of the polishing pad, or the like.

In an example embodiment, the driver 41 may selectively provide different movement paths for each operation mode.

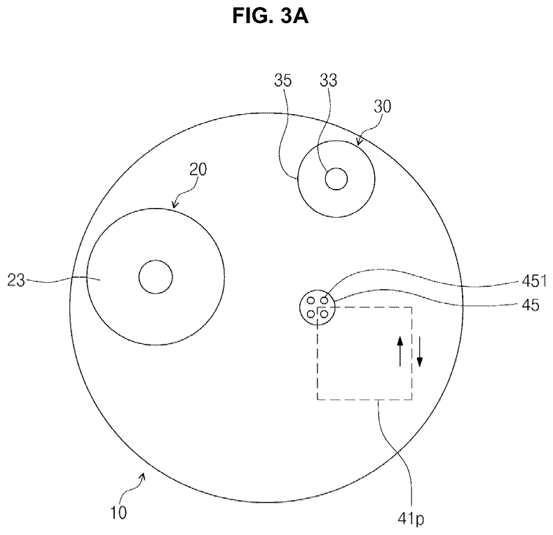

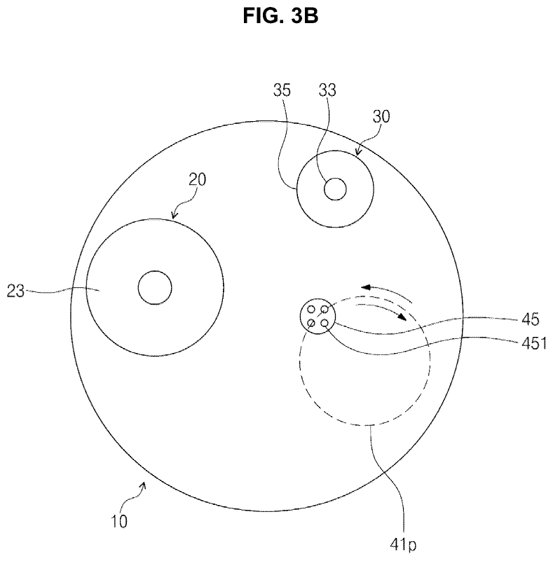

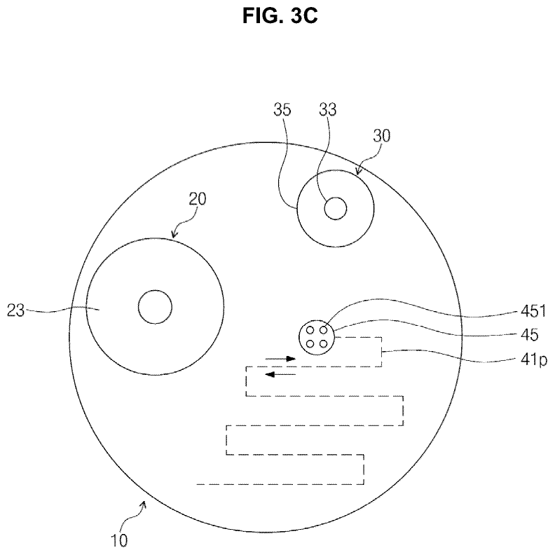

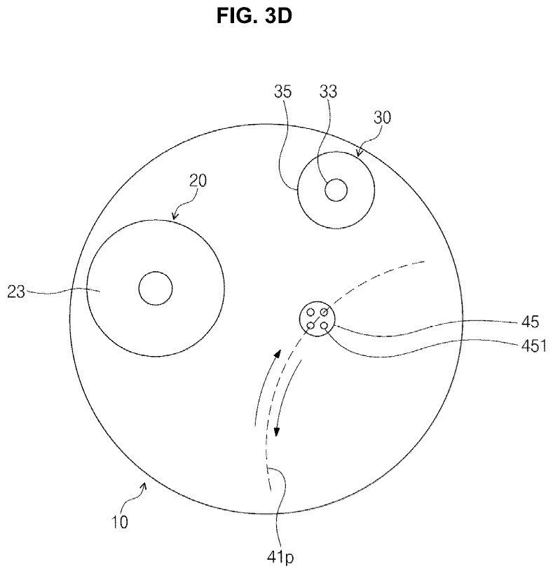

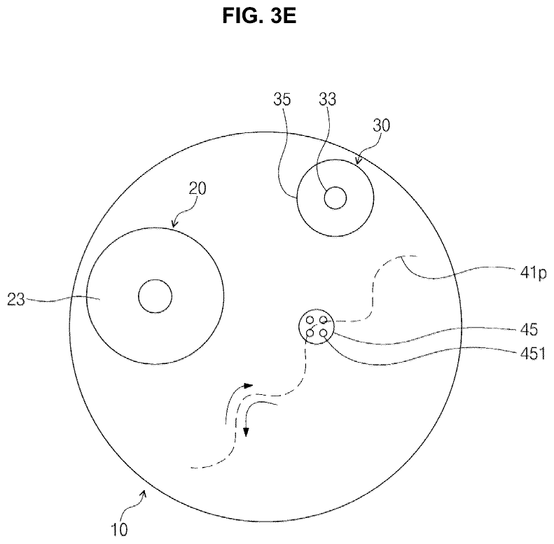

FIGS. 3A to 3E are plan views illustrating movement paths of the polishing fluid supply device 40 depending on various operation modes. In FIGS. 3A to 3E, portions represented by dashed lines indicate trajectories that appear when the center of the polishing fluid supply nozzle 45 moves, respectively. Hereinafter, operation modes of FIGS. 3A to 3E will be referred to as first to fifth operation modes, respectively. In the embodiment, the first to fifth operation modes are provided as examples, and other operation modes may be used.

Referring to FIGS. 3A to 3E, the polishing fluid supply nozzle 45 may discharge polishing fluid onto the polishing pad while moving along different movement paths 41p according to the first to fifth operation modes.

Referring to FIGS. 3A and 3B, in the first and second operation modes, the movement paths 41p of the polishing fluid supply nozzle 45 corresponding to the operation modes may have a closed figure shape.

For example, in the first operation mode, the movement path 41p of the polishing fluid supply nozzle 45 may have a polygonal shape, such as a rectangular shape, as illustrated in FIG. 3A. The polishing fluid supply nozzle 45 may move on at least a portion of sides forming the polygon. For example, the polishing fluid supply nozzle 45 may sequentially perform rotational motion along each side of the polygon. When the polishing fluid supply nozzle 45 moves rotationally, a movement direction of the polishing fluid supply nozzle 45 may be clockwise or counterclockwise. In the drawing, clockwise and counterclockwise directions are indicated by arrows, respectively.

Referring to FIG. 3B, in the second operation mode, the movement path 41p of the polishing fluid supply nozzle 45 may have a circular shape. For example, the polishing fluid supply nozzle 45 may move along a periphery. The polishing fluid supply nozzle 45 may move clockwise or counterclockwise. In the embodiment, the movement path 41p of the polishing fluid supply nozzle 45 is illustrated as having a circular shape, but example embodiments are not limited thereto. The movement path 41p of the polishing fluid supply nozzle 45 may have an elliptical shape or another closed figure shape similar to a circular or elliptical shape.

In an example embodiment, the movement path 41p of the polishing fluid supply nozzle 45 may have a shape other than a polygon or a circle. For example, the movement path 41p of the polishing fluid supply nozzle 45 may have a closed figure shape including at least one side formed of a straight line and a side formed of a curve. Because the polishing fluid supply nozzle 45 has a closed figure shape, the polishing fluid supply nozzle 45 may return to an initial location of the polishing fluid supply nozzle 45 when moving along a side in one direction. Accordingly, the polishing fluid supply nozzle 45 may continuously rotate clockwise or counterclockwise. However, the movement path 41p of the polishing fluid supply nozzle 45 is not limited thereto. The polishing fluid supply nozzle 45 may reciprocate along a portion of the closed figure.

Referring to FIGS. 3C to 3E, in the third to fifth operation modes, the movement path 41p of the polishing fluid supply nozzle 45 may be a linear shape rather than a closed figure shape. The polishing fluid supply nozzle 45 may move from linear one end of a linear shape to the other end of a linear shape, or vice versa. The polishing fluid supply nozzle 45 may reciprocate between one end of a linear shape and the other end of a linear shape. However, example embodiments are not limited thereto, and the polishing fluid supply nozzle 45 may move on a portion of the linear movement path 41p. In the third to fifth modes, the movement path 41p may include various types of lines.

Referring to FIG. 3C, in the third operation mode, the movement path 41p may include a plurality of sequentially connected straight lines. Some of the plurality of straight lines may have a direction different from a direction of the remaining straight lines, and some segments that are not adjacent to each other may be parallel to each other. For example, the movement path 41p may have a zigzag shape.

Referring to FIG. 3D, in the fourth operation mode, the movement path 41p may include a curve. The curve forming the movement path 41p may be a portion of a circle or an ellipse. For example, the curve forming the movement path 41p may have an arc shape.

Referring to FIG. 3E, in the fifth operation mode, the movement path 41p may include a curve and have at least one inflection point. The movement path 41p may have, for example, a sine curve shape.

As described above, various movement paths 41p of the polishing fluid supply nozzle 45 may supply slurry at an appropriate location according to the polishing conditions. For example, according to the polishing conditions, a polishing process may be performed in one of a plurality of operation modes, and a polishing process may then be performed in one of the remaining modes of the plurality of modes. For example, a polishing process may be performed in the second operation mode, and a polishing process may then be performed in the fifth operation mode.

In an embodiment, a polishing process may be designated to be performed in selected operation modes among a plurality of operation modes, and a polishing process may be performed in some of the selected operation modes or in the remaining modes, other than some of the selected operation modes, according to polishing conditions. For example, a polishing process may be selected to be performed in the fifth and first operation modes, and a polishing process may be performed in the first operation mode, and a process may then be performed the fifth operation mode according to the polishing conditions.

In an embodiment, such operation modes may be changed based on predetermined polishing conditions and how the polishing conditions change over time. For example, the selection of one of the plurality of operation modes and/or the change of one operation mode to another operation mode may be determined based on sizes of polishing particles in polishing fluid. For example, a polishing process may be performed in the first mode when the sizes of the polishing particles is less than or equal to a predetermined size, and may be performed in the second mode when the sizes of the polishing particles is larger than the predetermined size. The first mode may be an arc sweeping mode, and the second mode may be a rectangular sweeping mode.

In an embodiment, the selection of one of the plurality of operation modes and/or the change of one operation mode to another operation mode may be selected based on the usage time of a polishing pad. The polishing pad is a consumable component that needs to be replaced after a predetermined period of use, and a state of the polishing pad may change depending on the usage time of the polishing pad. For this reason, the polishing process may be performed in the first mode when it is determined that the usage time of the polishing pad is within a predetermined time, and may be performed in the second mode when it is determined that the usage time exceeds the predetermined time. For example, the first mode may be an arc sweeping mode, and the second mode may be a zigzag mode.

In an example embodiment, the polishing fluid supply nozzle 45 may continuously supply a uniform amount of polishing fluid SL onto the polishing pad 13. However, example embodiments are not limited thereto, and the polishing fluid supply nozzle 45 may discontinuously supply the polishing fluid SL onto the polishing pad 13. In an embodiment, the polishing fluid supply nozzle 45 may provide the polishing fluid SL after changing the amount of the polishing fluid SL depending on a location or supply time of the polishing fluid supply nozzle 45. Such a polishing fluid supply mode may be determined in consideration of the movement path 41p of the polishing fluid supply nozzle 45, or may be determined independently of the movement path 41p.

As described above, in the polishing fluid supply nozzle 45 according to an example embodiment, a portion to which the connector 43 is attached may move along a predetermined path on the platen to significantly reduce the restriction on the movement path 41p and simultaneously increase the degree of freedom of movement.

Each of the movement paths 41p in FIGS. 3A to 3E may be implemented by manufacturing the driver 41 (see FIG. 2) having a shape corresponding to each of the movement paths 41p and connecting the connector 43 (see FIG. 2) and the polishing fluid supply nozzle 45 to the driver 41. When the driver 41 is provided in the form of a rail, the rail may have various shapes to provide a path corresponding to each operation mode. For example, each rail may be one of a rectangular rail, a circular rail, an arc-shaped rail, or a linear rail.

In addition, a shape of the rail of the driver 41 may not be initially determined to be a specific movement path 41p. For example, a location and a movement direction of the driver 41 may be freely determined based on a control signal from the controller 50. The driver 41 may include an X-axis rail, through which the connector 43 and the polishing fluid supply nozzle 45 move in an X-axis direction, and a Y-axis rail through which the connector 43 and the polishing fluid supply nozzle 45 move in a Y-axis direction. The connector 43 and the polishing fluid supply nozzle 45, connected to the X-axis rail and the Y-axis rail, may receiving a location signal or a movement signal from the controller 50 to freely move in the X-axis direction and/or the Y-axis direction.

According to an example embodiment, the polishing fluid supply device may be moved along various paths on the polishing pad through various types of rails. An area, within which the polishing fluid supply device is movable, may correspond to the entire area other than an area in which a CMP assembly and a conditioner assembly are mounted. Unlike an example embodiment, when a polishing process is performed using a fluid supply arm extending in a radial direction of the platen from an outer side of the platen, a moving radius of the fluid supply arm may be limited. The moving radius of the fluid supply arm may allow only a circular arc-shaped movement path centered on a rotation axis fixed to the outer side of the platen.

In the movement path of the fluid supply arm, a central angle of the arc shape may be only about, for example, 20 degrees. In an embodiment, even when covering as wide an area as possible, the central angle of the arc may be only about 40 degrees. When the polishing fluid is supplied using the fluid supply arm, the polishing fluid may be provided only to a portion of the entire area other than the area in which the CMP assembly and conditioner assembly are mounted. Accordingly, the polishing fluid is unable to be supplied to various locations of the polishing pad, uneven accumulation of the polishing fluid may not be prevented as a polishing process is performed. In contrast, the polishing fluid supply device according to an example embodiment may supply the polishing fluid to the entire area other than the area in which the CMP assembly and conditioner assembly are mounted, so that uneven accumulation of the polishing fluid may be prevented during a polishing process.

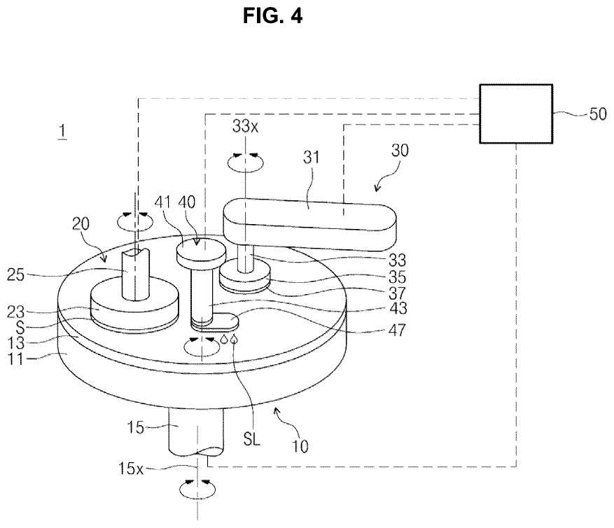

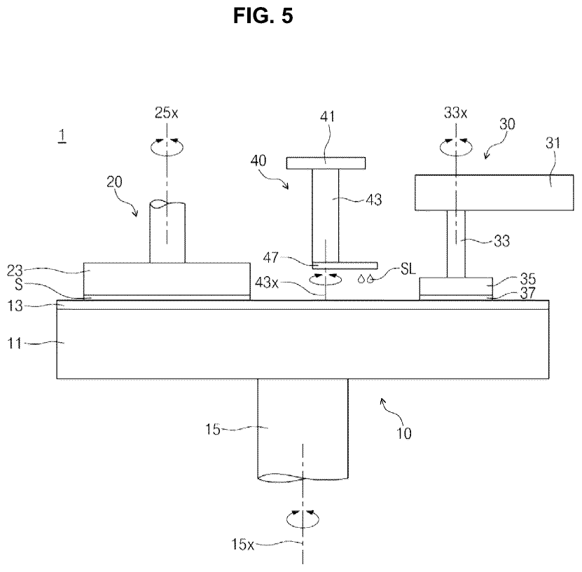

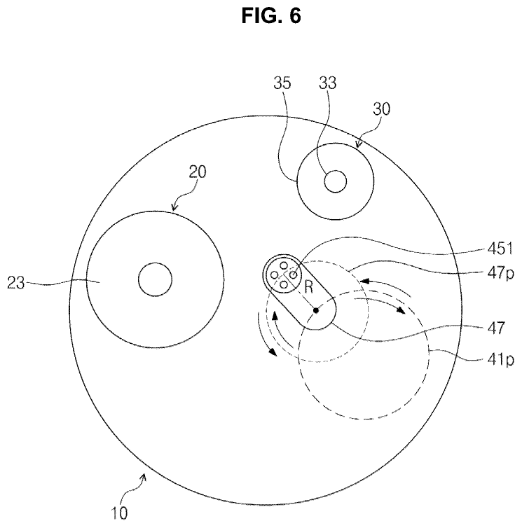

FIG. 4 is a perspective view illustrating a polishing apparatus according to an example embodiment. FIG. 5 is a schematic cross-sectional view of the polishing apparatus of FIG. 4, and FIG. 6 is a plan view illustrating a path of a polishing fluid supply device in the polishing apparatus of FIG. 4. In the following embodiments, differences from the above-described embodiments will be mainly described to avoid repetition.

Referring to FIGS. 4 to 6, a polishing fluid supply device 40 may include a driver 41, a connector 43 connected to the driver 41, and a rotatable rotary nozzle 47 provided on a lower end of the connector 43.

The polishing fluid supply device 40 may move along a movement path having the same shape as illustrated in FIGS. 3A to 3E.

The rotary nozzle 47 may rotate about a rotation axis of the connector 43. In an embodiment, a drive motor may be provided in the connector to drive the rotary nozzle 47, and may provide a rotational force to the rotary nozzle 47 the connector 43.

The rotary nozzle 47 may have a shape of a plate elongated in one direction. One end portion of the rotary nozzle 47 in a length direction may be connected to the connector 43. The rotary nozzle 47 may have a concave portion at a center and/or one side rotary nozzle 47, and at least one polishing fluid supply port 451 may be provided in the concave portion. The at least one polishing fluid supply ports 451 may be provided on a portion opposing the one end portion connected to the connector 43, for example, the other end portion. The polishing fluid supply nozzle 45 connected to the connector 43 may receive a rotational force from a drive motor. The polishing fluid supply port 451 may rotate along a circle having a predetermined rotation radius R about the rotation axis 43x of the connector 43.

In an example embodiment, the polishing fluid supply device 40 may have a movement path that is a combination of the above-described movement path and a rotary nozzle movement path 47p formed by rotation of polishing fluid supply device 40. Accordingly, an area that is able to be covered by moving the polishing fluid supply nozzle 45 may be further increased, resulting in an increased degree of freedom of the location of the polishing fluid SL when the polishing fluid SL is supplied.

In the above-described embodiment, the rotary nozzle 47 may provide an additional movement path 47p and the additional movement path is illustrated as having a circular shape, but example embodiments are not limited thereto.

According to an example embodiment, the polishing fluid supply nozzle 45 may provide an additional movement path, and the additional movement path may have a linear shape.

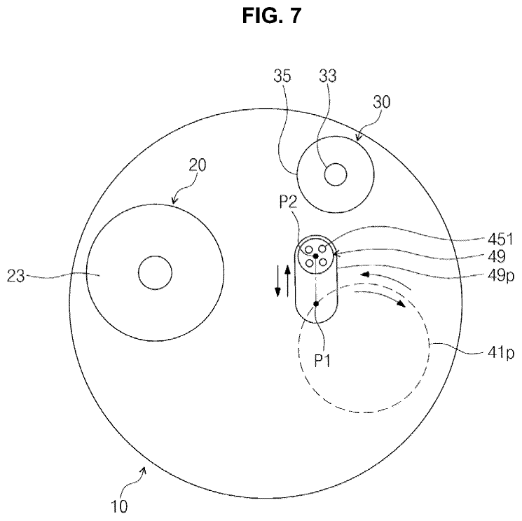

FIG. 7 is a plan view illustrating a path of the polishing fluid supply device 40 in the polishing apparatus of FIG. 4.

Referring to FIGS. 4, 5, and 7, the polishing fluid supply device 40 may include the driver 41, the connector 43 connected to the driver 41, and the rotatable linear nozzle 49 provided on a lower end of the connector 43.

The linear nozzle 49 may have a shape of a plate elongated in one direction. The linear nozzle 49 may perform linear motion while being connected to the connector 43. The linear nozzle 49 may have a concave portion at a center and/or one side of the linear nozzle 49, and at least one polishing fluid supply port 451 may be provided in the concave portion.

A drive motor may be provided in the connector 43 to perform linear motion of the linear nozzle 49 in a length direction. The polishing fluid supply nozzle 45, connected to the connector, 43 may be supplied with power for linear reciprocating motion through the drive motor. For example, the polishing fluid supply nozzle 45 may perform linear reciprocating motion from point P1 to point P2 using the power from the drive motor.

In an example embodiment, the polishing fluid supply device 40 may have a movement path in which the above-described movement path 41p and a movement path 49p, formed by reciprocation of the linear nozzle 49, are combined. Accordingly, the area that is able to be covered by moving the polishing fluid supply nozzle 45 may be further increased, resulting in an increased degree of freedom of the location of the polishing fluid SL when the polishing fluid SL is supplied.

In an example embodiment, in FIGS. 6 and 7, the polishing fluid supply nozzle is illustrated as having a shape elongated in one direction in plan view. However, example embodiments are not limited thereto, the polishing fluid supply nozzle may have various shapes as long as it provides an additional movement path of the polishing fluid supply port 451.

In the polishing apparatus according to an example embodiment, the polishing fluid supply device may operate, as described below.

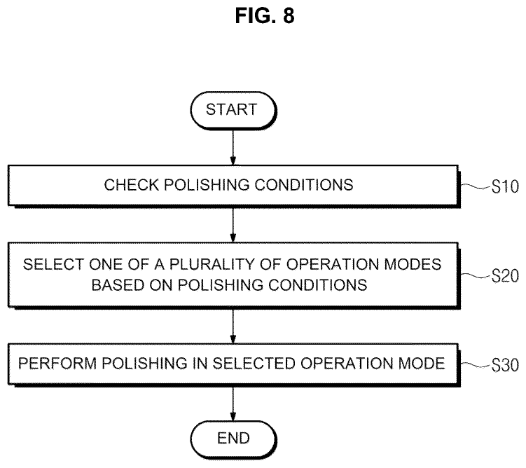

FIG. 8 illustrates a method of performing a polishing process using a polishing apparatus according to an example embodiment. Referring to FIG. 8, the polishing process may include checking polishing conditions (operation S10), selecting one of a plurality of operation modes based on the polishing conditions (operation S20), and performing polishing in the selected mode (operation S30).

The checking the polishing conditions may be checking an object to be polished, polishing fluid, and polishing process conditions. For example, the checking the polishing conditions may be checking a pressure applied to a target substrate that is the object to be polished, a flow rate of the polishing fluid, sizes of polishing particles, the life of a polishing pad, rotational speed of a platen, rotational speed of a CMP pad, or the like. In an embodiment, the checking the polishing conditions may include checking a state of the polishing apparatus before starting a current process in the case of a polishing apparatus on which a polishing process has already been performed.

The checking the state of the polishing apparatus before the start of the current process may include checking a height of the polishing fluid at two different points on the polishing pad. The height of the polishing fluid may refer to a height of a stack in which solids in the polishing fluid, such as polishing particles and additives are accumulated, or a height of a stack containing a solvent.

The two different points on the polishing pad refer to two points that are at different distances from a center of the polishing pad in a radial direction. For example, the center may be a first point, and a midpoint between the center and an edge may be a second point. In an embodiment, a point at a first distance from the center in the radial direction may be a first point, and a point at a second distance further from the center in the radial direction may be a second point.

When polishing is continuously performed using the polishing apparatus, the polishing fluid is unevenly accumulated on the polishing pad due to centrifugal force generated by rotation of the platen and the polishing pad. For example, the polishing fluid may accumulate more on an outer side of the polishing pad than on a center of the polishing pad. Accordingly, a height of the second point may be greater than a height of the first point. A difference in heights between the two points of the polishing fluid may vary depending on various polishing conditions, such as a supply location of the polishing fluid, sizes of polishing particles in the polishing fluid, aggregation of the polishing particles, and a flow rate of the polishing fluid, and may increase with increasing usage time of the polishing apparatus.

In an example embodiment, the first and second points may be selected during the polishing process, and the heights of the first and second points may be measured. In the embodiment, when the difference in heights between the first and second points is greater than or equal to a predetermined value, a predetermined operation mode may be selected and the polishing process may be performed in the selected operation mode. When the difference in heights between the first and second points is less than the predetermined value, another predetermined operation mode may be selected and the polishing process may be performed in the selected operation mode.

The heights of the first and second points may be measured in-situ during the polishing process, but example embodiments are not limited thereto. The heights of the first and second points may be measured after one polishing process is completed and before another polishing process starts.

In an example embodiment, at least one polishing condition other than the difference in heights between the two points may be checked, and one of the next operation modes may be selected based on the checked polishing condition. For example, when the sizes of the polishing particles is greater than or equal to a predetermined size, a specific operation mode, for example, a third operation mode, may be selected because a height at the second point becomes greater than a height at the first point. In an embodiment, when the polishing pad has been used for a predetermined period of time or longer, a specific operation mode, for example, a fifth operation mode, may be selected because the amount of polishing particles stacked on the polishing pad is increased.

In an example embodiment, when there is a polishing process which has already been performed, the operation mode may change from one operation mode used in the polishing process, which has already been performed, to another operation mode. The operation mode may change to another operation mode after one polishing process is completed and before another polishing process starts. In an embodiment, the operation mode may change to another operation mode during one polishing process. The mode of the polishing fluid supply device may change simultaneously with a polishing substrate of the target substrate.

In an example embodiment, the selecting one of the plurality of operation modes may be based on data obtained by directly experimenting or simulating operation modes according to each polishing condition. The experimented and/or simulated data for each polishing condition may be combined with the operation mode and then provided in the form of a look-up table. The controller may obtain at least one of the polishing conditions and then easily select the operation mode based on the polishing condition provided in the form of the look-up table. Then, the polishing process may be performed in the selected operation mode.

According to an example embodiment, changing the operation mode of the polishing fluid supply device may allow a distribution of the supplied polishing fluid in a radial direction of the polishing pad to be changed. For example, changing the operation mode of the polishing fluid supply device may allow a height of the polishing fluid on the polishing pad to be changed. When the height of the polishing fluid has a substantially uniform value at any point on the polishing pad, the uniformity of polishing may be ensured. According to an example embodiment, changing the operation mode of the polishing fluid supply device may allow the height of the polishing fluid to be uniformly maintained in the radial direction of the polishing pad.

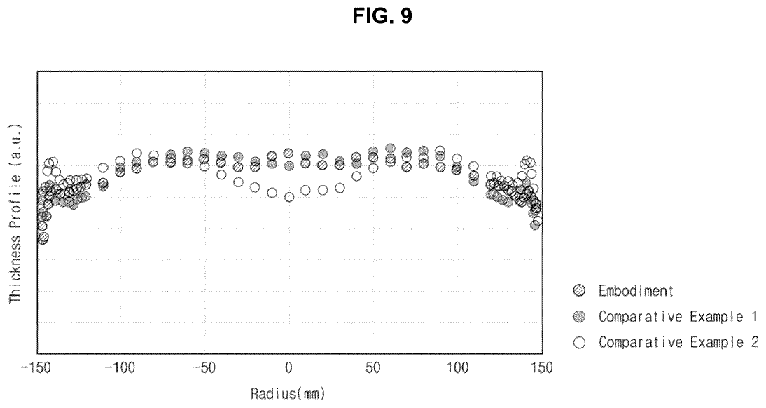

FIG. 9 illustrates a polishing profiles in a radial direction of a polishing pad before and after changing operation mode of a polishing fluid supply device. In FIG. 9, a graph indicated as “Comparative Example 1” is a graph of polishing profile in a radial direction of a polishing pad when a polishing process is performed using a new polishing pad, and a graph indicated as “Comparative Example 2” is a graph of polishing profile in the radial direction of the polishing pad after a polishing process is performed for a predetermined time. A graph indicated as Embodiment is a graph of polishing profile in a radial direction of a polishing pad after a polishing process is performed for the same predetermined time as in Comparative Example 2, and an operation mode of a polishing fluid supply device has been changed once or more based on polishing conditions.

Referring to FIG. 9, as seen in Comparative Example 1, in the case of a new polishing pad on which the polishing process has hardly been performed, the degree of polishing in the center is almost similar to the degree of polishing between the center and an edge.

However, as seen in Comparative Example 2, as a polishing process is performed, a deviation of polishing profile within the polishing pad is increased, resulting in a central portion having a significantly small heights compared to other portions.

In an example embodiment, polishing fluid having a height profile, almost similar to that of a new polishing pad, was confirmed although a polishing process was performed for the same time as in Comparative Example 2. For example, a uniform polishing profile may be obtained even by controlling the operation mode of the polishing fluid supply device based on polishing conditions as in the example embodiment.

Returning to FIGS. 1 and 2, the polishing apparatus 1 may further include a cleaning solution supply device that supplies a cleaning solution for cleaning the target substrate S and the polishing pad 13 after the polishing process. The cleaning solution may be supplied to the target substrate S and the polishing pad 13 by the cleaning solution supply device to remove polishing particles remaining on the surface to be processed of the target substrate S and the polishing pad 13 or processing products generated by the polishing process. Deionized (DI) water may be used as the cleaning solution. In addition to the DI water, an appropriate chemical solution may be supplied as the cleaning solution depending on the type of polishing particles. The cleaning solution supply device may include a cleaning solution supply nozzle for supplying the cleaning solution to a predetermined location on the polishing pad 13. The cleaning solution supply nozzle may be moved in a form, similar to that of the polishing fluid supply nozzle 45, and may supply the cleaning solution to an arbitrary location on the polishing pad 13.

The polishing apparatus 1 having the above-described structure may supply the polishing fluid SL, containing polishing particles, to the polishing pad 13 to polish the target substrate S while rotating the platen 11 and/or the CMP head 23.

The polishing pad 13 and the platen 11 may rotate about the rotation axis 15x of the drive spindle 15. The target substrate S may be pressed against the polishing pad 13 by the CMP head 23, and may be polished by moving the CMP head 23 within a plane of the platen 11.

In the polishing apparatus having the above-described structure, while rotating each of the platen 11 and the disk head 35, the conditioner disk 37 may be placed on the polishing pad 13 by the disk head 35 and then pressed, and the disk head 35 may be moved within an upper surface of the platen 11 to perform a conditioning process of the polishing pad 13.

As described above, the polishing apparatus according to an example embodiment may provide polishing fluid to a polishing pad through various paths to provide a uniform polishing profile. In an example embodiment, solids in the polishing fluid, for example, polishing particles and additives added to the polishing fluid, may have a size of several nanometers to reduce scratches, or the like, on the target substrate caused by foreign objects during the polishing process. The polishing fluid, for example, the polishing particles and additives, may be unevenly accumulated at a specific location due to centrifugal force, or the like, as the polishing process is continuously performed. The polishing fluid, unevenly accumulated at a specific location, may cause non-uniform polishing. In an example embodiment, such uneven accumulation of the polishing fluid may be prevented by supplying the polishing fluid while moving the polishing fluid supply device in various operation modes.

The polishing apparatus may constitute a planarization apparatus together with a loading/unloading device, a cleaning device, a drying device, and the like. The loading/unloading device, the polishing apparatus, the cleaning device, the drying device, and the like, may be connected to the controller 50. Various operations of the polishing apparatus may be controlled by the controller 50. The planarization apparatus may include a single polishing apparatus or a plurality of polishing apparatuses. A target substrate may be transferred to the loading/unloading device, the polishing apparatus, the cleaning device, the drying device, and the like, by a transfer device to implement planarization. Use of the planarization apparatus may allow a planarization process according to the polishing of the target substrate to be performed efficiently and continuously.

As set forth above, a polishing apparatus according to an example embodiment may significantly reduce defects that may occur due to uneven accumulation of polishing fluid.

While example embodiments have been shown and described above, it will be apparent to those skilled in the art that modifications and variations could be made without departing from the scope of the disclosure as defined by the appended claims.

What is claimed is:

1. A polishing apparatus comprising:
a platen configured to support a polishing pad, the platen being rotatable;
a chemical mechanical polishing (CMP) head on the platen, the CMP head being configured to hold a substrate to be processed;
a polishing fluid supply device configured to supply a polishing fluid onto the polishing pad, the polishing fluid supply device overlapping the platen in plan view;
a conditioner assembly configured to condition the polishing pad; and
a controller configured to control the platen, the CMP head, the polishing fluid supply device, and the conditioner assembly,
wherein the polishing fluid supply device comprises:
a polishing fluid supply nozzle configured to supply the polishing fluid onto the polishing pad;
a driver configured to move the polishing fluid supply nozzle; and
a connector configured to connect the polishing fluid supply nozzle and the driver, and
wherein the controller is configured to set a plurality of operation modes having respectively different moving paths for the polishing fluid supply device and select one operation mode of the plurality of operation modes, and
wherein the polishing fluid supply device is configured to move along a moving path corresponding to the selected operation mode.

2. The polishing apparatus of claim 1, wherein the polishing fluid supply nozzle is configured to move parallel to an upper surface of the platen.

3. The polishing apparatus of claim 1, wherein the driver comprises a rail.

4. The polishing apparatus of claim 1, wherein the polishing fluid supply nozzle is connected to a lower end of the connector, and
wherein the polishing fluid supply nozzle is configured to rotate.

5. The polishing apparatus of claim 1, wherein the polishing fluid supply nozzle is configured to rotate about the connector as a rotation axis.

6. The polishing apparatus of claim 1, wherein the polishing fluid supply nozzle is connected to a lower end of the connector, and
wherein the polishing fluid supply nozzle is a linear type nozzle configured to perform linear reciprocating motion.

7. The polishing apparatus of claim 1, wherein a plurality of moving paths overlap the platen in plan view.

8. The polishing apparatus of claim 7, wherein at least a portion of the plurality of moving paths has a closed figure shape, and
wherein the polishing fluid supply device is configured to rotate along the closed figure shape.

9. The polishing apparatus of claim 7, wherein the plurality of moving paths have a linear shape comprising a curve or a straight line, and
wherein the polishing fluid supply device is configured to reciprocate along at least a portion of the linear shape.

10. The polishing apparatus of claim 1, wherein the controller is configured to select one of the plurality of operation modes based on sizes of polishing particles in the polishing fluid.

11. The polishing apparatus of claim 1, wherein the controller is configured to select one of the plurality of operation modes based on usage time of the polishing pad.

12. The polishing apparatus of claim 1, wherein the controller is configured to:
select two points with different distances along a radial direction from a center of the polishing pad,
select a first operation mode of the plurality of operation modes when a height difference of the polishing fluid at the two points is greater than or equal to a predetermined value, and
select a second operation mode one of the plurality of operation modes when the height difference of the polishing fluid at the two points is less than the predetermined value.

13. The polishing apparatus of claim 1, wherein one of the plurality of operation modes is selected based on polishing conditions.

14. The polishing apparatus of claim 1, further comprises another polishing fluid supply device, wherein the polishing fluid supply device and the another polishing fluid supply device are independently driven.

15. The polishing apparatus of claim 14, wherein the polishing fluid supply device and the another polishing fluid supply device are selected to correspond to different operation modes, respectively.

16. A polishing method performed by the polishing apparatus of claim 1, the polishing method comprising:
checking polishing conditions;
selecting a first operation mode from among a plurality of operation modes based on polishing conditions; and
performing polishing in the selected first operation mode.

17. The polishing method of claim 16, wherein the selecting the single operation mode from among the plurality of operation modes comprises, when there is a previously performed polishing process in a second operation mode, selecting the first operation mode from among the plurality of operation modes, and
wherein the first operation mode is different from the second operation mode.

18. The polishing method of claim 16, further comprising:
selecting a third operation mode that is different from the first operation mode selected from among the plurality of operation modes; and
performing polishing in the selected third operation mode.

19. The polishing method of claim 16, wherein the polishing conditions comprise sizes of polishing particles in a polishing fluid.

20. The polishing method of claim 16, wherein the polishing conditions comprise usage time of a polishing pad.
